(19) United States
(12) Patent Application Publication
(10) Pub. No.: US 2022/0007525 A1
(43) Pub. Date: Jan. 6, 2022

(54) ADJUSTING MECHANISM FOR TILE DISPLAY SCREENS AND TILED DISPLAY DEVICE

(71) Applicant: CHONGQING KONKA PHOTOELECTRIC TECHNOLOGY RESEARCH INSTITUTE CO., LTD., Chongqing (CN)

(72) Inventors: Guojian ZHANG, Chongqing (CN); Li-Wei KUNG, Chongqing (CN); Yang ZHOU, Chongqing (CN); Dong LIU, Chongqing (CN)

(21) Appl. No.: 17/479,533

(22) Filed: Sep. 20, 2021

Related U.S. Application Data
(63) Continuation of application No. PCT/CN2020/113591, filed on Sep. 4, 2020.

(30) Foreign Application Priority Data
Apr. 9, 2020 (CN) 202010275409.X

(51) Int. Cl. H05K 5/02; F16B 5/02; H05K 5/00

(52) U.S. Cl. CPC H05K 5/0217; H05K 5/0021; F16B 5/0225

(57) ABSTRACT

An adjusting mechanism for tile display screens and a tiled display device are provided. The adjusting mechanism for tile display screens is configured to adjust a gap between two adjacent tile display screens, and includes first support plates, a second support plate, and adjusting fixtures. The first support plates are used to fix the tile display screens in one to one correspondence and are movably connected to the second support plate. Each adjusting fixture is operable to be connected between two adjacent first support plates and includes two adjusting members in threaded connection. A threaded connection length between the two adjusting members is adjustable so that the gap between at least two tile display screens is adjusted.

### CROSS-REFERENCE TO RELATED APPLICATIONS

The present application is a continuation of International Application No. PCT/CN2020/113591, filed on Sep. 4, 2020, which claims priority to Chinese Patent Application No. 202010275409.X, filed on Apr. 9, 2020, the disclosures of which are hereby incorporated by reference in their entireties.

### TECHNICAL FIELD

The disclosure relates to the technical field of tile display screens, and particularly to, an adjusting mechanism for tile display screens and a tiled display device.

### BACKGROUND

A tiled screen is a complete tiled liquid-crystal display unit which can be used as a display separately, and can also be tiled into an oversize screen for use. According to different usage demands, variable large-screen functions for making the screen bigger or smaller are achieved, such as single-screen split display, single-screen separate display, arbitrary combined display, full-screen liquid crystal tiling, and portrait display, with optional compensation or covering of image frames.

At present, many tiled screens on the market are tiled by a method of firstly fixing a metal frame, and then fixing the tile display screens on the metal frame one by one, thereby finishing tiling work of the tiled screens.

It is apparent that this tiling method and tiling structure cannot achieve the purpose of adjusting degrees of freedom of the tile display screens. While processing precision of the metal frame will directly affect the tiling effect of the tiled screen. When the processing precision of the metal frame is insufficient, tiling gaps will be generated between the tile display screens (including a horizontal gap between adjacent tile display screens arranged in the same row, and a longitudinal gap between adjacent tile display screens arranged in the same column), and the tiling gaps cannot be eliminated, resulting in a direct influence to the display effect of the tiled screen.

Thus, the conventional art still needs to be improved and developed.

### SUMMARY

In view of disadvantages of the conventional art described above, the objective of the disclosure is to provide an adjusting mechanism for tile display screens and a tiled display device, intended to reduce one type of a transverse gap and a longitudinal gap between tile display screens, and reduce influences of the tiling gaps to the display effect of an overall tiled screen.

The disclosure has the following technical solutions.

An adjusting mechanism for tile display screens is configured to adjust a gap between two adjacent tile display screens, including first support plates and a second support plate. Each first support plate is configured to fix a corresponding one of the tile display screens, and the first support plates and the second support plate are movably connected.

The adjusting mechanism further includes adjusting fixtures. Each adjusting fixture is operable to be connected between the two adjacent first support plates and includes two adjusting members in threaded connection, and a threaded connection length between the two adjusting members is adjustable so that the gap between the at least two tile display screens is adjusted.

In an implementation, each edge of one surface, away from the tile display screen, of the first support plate is provided with at least one adjusting fastener which is exposed from a hollow portion disposed on the second support plate, and the adjusting fixture is clamped with the corresponding adjusting fasteners.

In an implementation, each adjusting fastener defines a groove, and the two adjusting members of each adjusting fixture are respectively clamped in the grooves of the adjacent adjusting fasteners so as to connect the two adjacent support plates.

In an implementation, each adjusting member includes a retaining portion clamped with the corresponding groove, and limiting portions respectively disposed at two ends of the retaining portion.

In an implementation, the groove is in a U-shape.

In an implementation, the adjusting fasteners include longitudinal adjusting fasteners and transverse adjusting fasteners, the longitudinal adjusting fasteners are configured to cooperate with the adjusting fixtures to adjust the longitudinal gap between the tile display screens, and the transverse adjusting fasteners are configured to cooperate with the adjusting fixtures to adjust the transverse gap between the tile display screens.

In an implementation, one surface, facing the tile display screen, of the first support plate is provided with at least one alignment mark that is used to mark a fixation position of the tile display screen.

In an implementation, one surface, facing the tile display screen, of the first support plate is provided with a third support plate. Each third support plate is configured to fix a corresponding one of the tile display screens, and the first support plate is movably connected with the third support plate.

In an implementation, each third support plate is provided with at least one alignment mark that is used to mark a fixation position of the tile display screen.

In an implementation, a first threaded hole is formed in the middle of the third support plate, a first through hole is formed in the middle of the first support plate, and the first support plate and the third support plate are connected through a first bolt that penetrates the first through hole and is screwed into the first threaded hole.

In an implementation, a diameter of the first through hole is greater than a nominal diameter of the first threaded hole.

In an implementation, each edge of the first support plate is provided with two adjusting fasteners that are exposed from hollow portions disposed on the second support plate, and two adjusting fasteners on the same side are disposed in parallel.

In an implementation, each edge of one surface, away from the tile display screen, of the first support plate, is provided with at least two adjusting fasteners, the two adjusting fasteners on the same side are arranged in parallel and have an interval reserved there between, and the adjusting fasteners are exposed from hollow portions disposed on the second support plate.

In an implementation, the second support plate is provided with a plurality of second through holes, the first support plates are provided with a plurality of second threaded holes corresponding to the second through holes one by one, and the first support plates and the second support plate are connected through second bolts that respectively penetrate the second through holes and are screwed into the second threaded holes.

In an implementation, a diameter of each second through hole is greater than a nominal diameter of each second threaded hole.

A tiled display device includes at least two tile display screens and an adjusting mechanism for tile display screens described above. Thus, the tiled display device may have all features and effects of the above-mentioned adjusting mechanism for tile display screens, so no more elaboration will be made.

Compared with the conventional art, the adjusting mechanism for tile display screens provided by the disclosure is configured to adjust a gap between two adjacent tile display screens, and includes first support plates, a second support plate and adjusting fixtures. The first support plates are used to fix the tile display screens in one to one correspondence and are movably connected to the second support plate; each adjusting fixture is connected between two adjacent first support plates and includes two adjusting members in threaded connection, and a threaded connection length between the two adjusting members is adjustable so that the gap between at least two tile display screens is adjusted. The adjusting mechanism for tile display screens provided by the disclosure can utilize characteristics of the threaded connection; by adjusting the threaded connection length of the two adjusting members (the longer the threaded connection length between the two, the smaller the distance between two adjacent first support plates), the interval between two adjacent first support plates can be adjusted, so that the transverse gap or the longitudinal gap (which is determined according to an arrangement direction of the adjacent tile display screens) of the two adjacent tile display screens is reduced and even eliminated, and influences of the tiling gaps to the display effect of the overall tiled screen are reduced.

### BRIEF DESCRIPTION OF THE DRAWINGS

FIG. 1 is a local schematic structural diagram of an adjusting mechanism for tile display screens according to an implementation of the disclosure.

FIG. 2 is a schematic structural diagram of an adjusting mechanism for tile display screens according to an implementation of the disclosure.

FIG. 3 is an explosive view of an adjusting fixture for the adjusting mechanism for tile display screens of the disclosure.

FIG. 4 is a sectional view from the first perspective of an adjusting mechanism for tile display screens according to an implementation of the disclosure.

FIG. 5 is a sectional view from the second perspective of the adjusting mechanism for tile display screens according to an implementation of the disclosure.

FIG. 6 is a schematic diagram of positions of alignment marks in an implementation of the disclosure.

FIG. 7 illustrates a schematic structural diagram of an adjusting mechanism for tile display screens according to another implementation of the disclosure.

FIG. 8 is a schematic structural diagram of an adjusting mechanism for tile display screens according to an implementation of the disclosure.

FIG. 9 is a schematic structural diagram of a second support plate according to an implementation of the disclosure.

FIG. 10 is a schematic structural diagram of a second support plate used in another implementation of the disclosure.

FIG. 11 is a schematic diagram of a tiled status of a plurality of tile display screens.

### DETAILED DESCRIPTION

The disclosure provides an adjusting mechanism for tile display screens and a tiled display device. In order to make the objective, technical solutions and effects of the disclosure clearer and more definite, the disclosure will further be described below with reference to the drawings and examples in detail. It is to be understood that the specific implementations described herein are merely intended to explain the disclosure and not limit the disclosure.

The problem with the existing tile display screen mounting structure is that since a fixed metal frame is configured to mount tile display screens, mounting positions of the tile display screens are determined after the metal frame is selected, and no adjustment can be made. If there is a transverse gap and/or a longitudinal gap thereafter, the display effect of the overall tiled screen will be directly affected. If the positions of the tile display screens can be adjusted transversely or longitudinally during mounting, the tiling gaps between the tile display screens may be eliminated or reduced. It is to be noted that the disclosure is intended to eliminate at least one type of the transverse gap or the longitudinal gap, the purpose of reducing influences of the tiling gaps to the overall tiled screen is achieved as long as one type of the tiling gaps can be eliminated, and thus it is not required to eliminate all the tiling gaps.

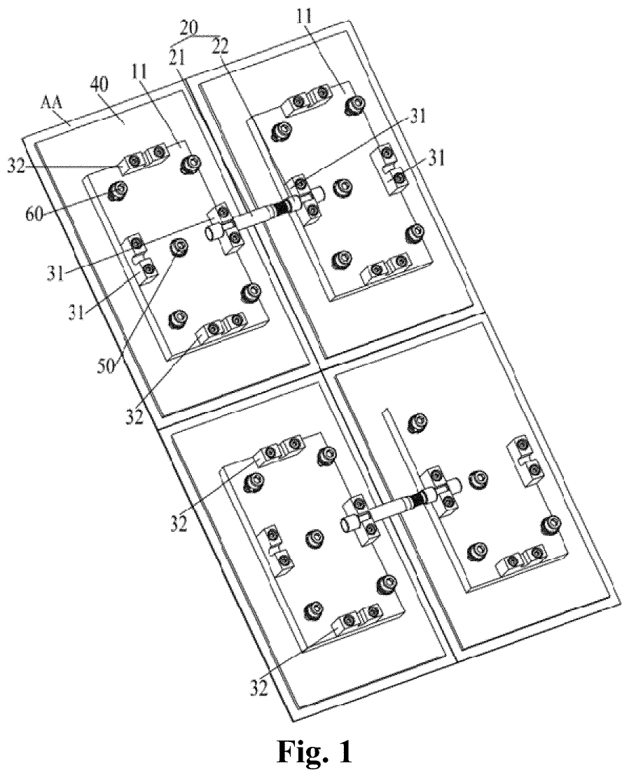

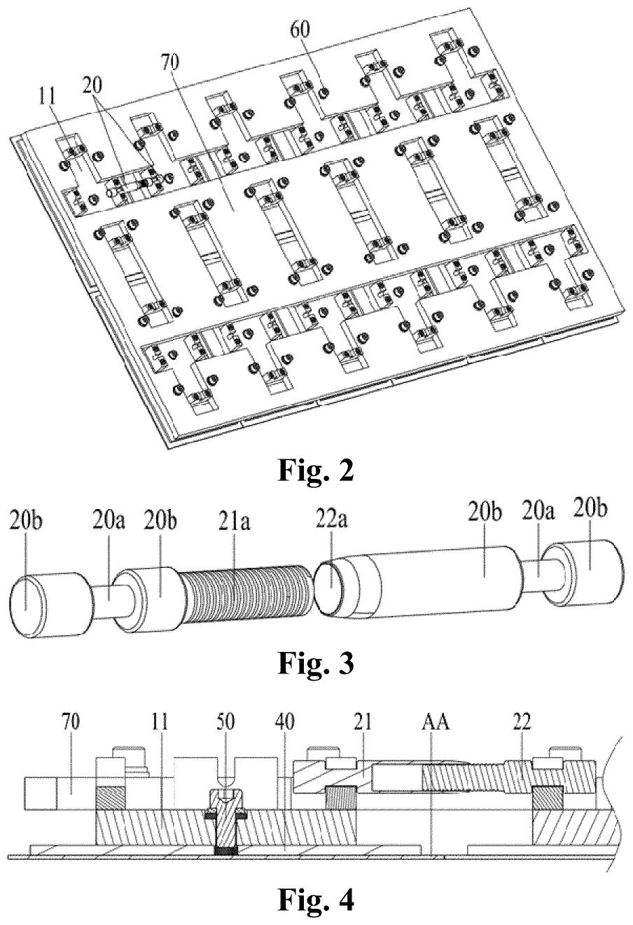

In view of above, the disclosure provides an adjusting mechanism for tile display screens. The adjusting mechanism is configured to adjust a gap between two adjacent tile display screens. As shown in FIGS. 1, 2 and 7, the adjusting mechanism includes first support plates 11, a second support plate 70, and adjusting fixtures 20. The first support plates 11 are used to fix the tile display screens AA in one to one correspondence. The second support plate 70 is used as a movable carrier of the first support plates 11. In other words, the second support plate 70 is used to support the first support plates 11, and the first support plates 11 are movable relative to the second support plate 70. The adjusting fixtures 20 are configured to adjust a position of at least one tile display screen (two adjacent tile display screens move relatively, or one of them is fixed while the other one is movable) to close a distance between the adjacent tile display screens, so as to reduce or eliminate the gap between the adjacent tile display screens.

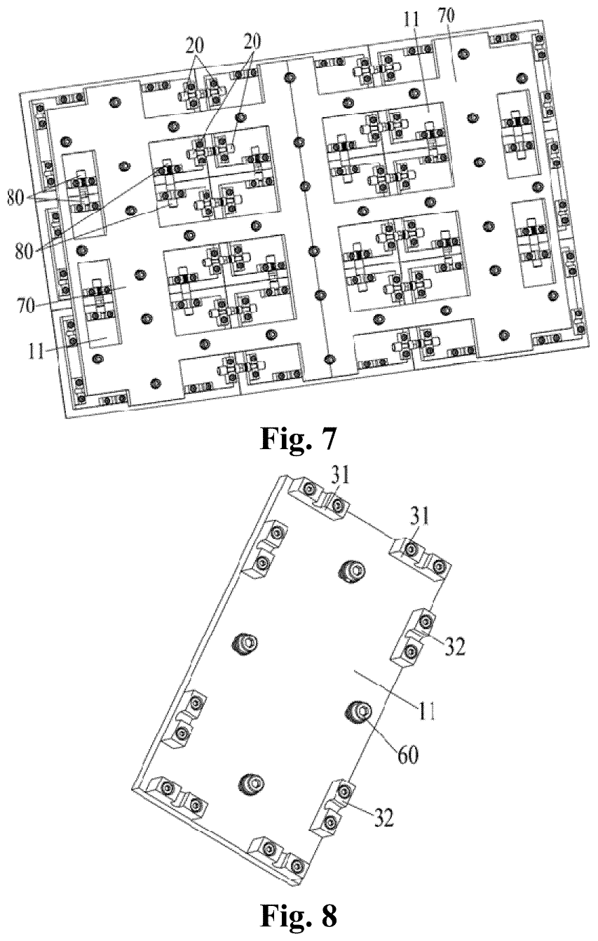

As an implementation of the disclosure, the second support plate 70 defines a hollow portion 71 (as shown in FIG. 9), each edge of one surface, away from the tile display screen, of the first support plate 11 is provided with at least one adjusting fastener which is exposed from the hollow portion 71. The adjusting fasteners are used to correspondingly fasten the adjusting fixtures (as shown in FIG. 1 and FIG. 7) so that the adjusting fixtures 20 may pull the adjusting fasteners to move, to in turn pull the first support plates 11 and the tile display screens.

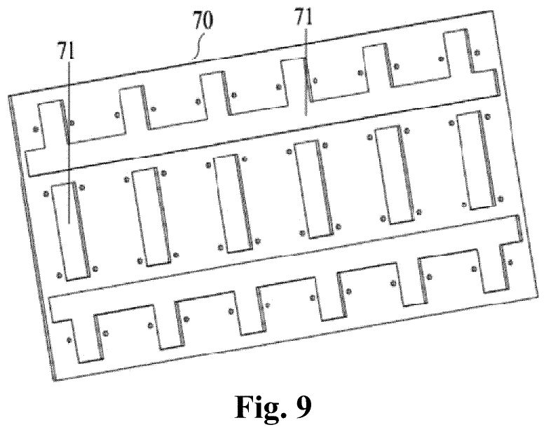

In an implementation, the adjusting fasteners include two types of adjusting fasteners, namely longitudinal adjusting fasteners 32 and transverse adjusting fasteners 31 (as shown in FIG. 1 and FIG. 8). The longitudinal adjusting fasteners 32 are configured to cooperate with the adjusting fixtures 20 to adjust the longitudinal gap between the tile display screens. The transverse adjusting fasteners 31 are configured to cooperate with the adjusting fixtures 20 to adjust the transverse gap between the tile display screens. The longitudinal adjusting fasteners 32 and the transverse adjusting fasteners 31 are of the same part configuration, and disposed in directions perpendicular to each other.

Further, the two adjusting members are both adjusting rods (a first adjusting rod 21 and a second adjusting rod 22 as shown in FIG. 1). As shown in FIG. 4 and FIG. 3, an end of the first adjusting rod 21 is provided with an adjusting threaded pin 21a. An end of the second adjusting rod 22, which faces the end of the first adjusting rod 21, defines an adjusting threaded hole 22a that is adapted to the adjusting threaded pin 21a. The longer the length of the adjusting threaded pin screwed into the adjusting threaded hole is, the smaller the distance between the adjacent first support plates 11 is.

In an implementation, one side, away from the first support plate 11, of each adjusting fastener defines a U-shaped groove. The two adjusting rods are both provided with retaining portions 20a that are operable to be retained in the U-shaped grooves (as shown in FIG. 3). Each adjusting member is provided with a limiting portion 20b at both ends of the retaining portion 20. A diameter of each retaining portion 20a is smaller than a diameter of each limiting portion 20b.

The reason why the grooves are configured to be U-shaped and the retaining portions 20a and the limiting portions 20b are disposed adaptively is to facilitate mounting and removing of the adjusting fixtures 20. That is, the adjusting fixtures 20 may be mounted to the adjusting fasteners as needed, and may be removed when not needed. When it is found that a gap is reversed between two adjacent tile display screens, the staff can place one adjusting fixture 20 in the corresponding adjusting fasteners, and then rotate the two adjusting members (or keep one of the adjusting members still and rotate another adjusting member), so as to reduce or eliminate the gap. When the gap is reduced to a certain degree or eliminated, the staff can remove the adjusting fixture 20. Thus, convenience in operation and low cost are achieved.

According to different thread precision of the adjusting members and different adjustment magnitude, the adjustment precision of a physical gap may theoretically reach a micron level at the minimum, so as to realize adjustment of display screens in various sizes, such as gapless tiling adjustment and adjustment of various tiling gaps as needed, thereby guaranteeing the best overall display effect of the large-sized tiled screen.

According to the disclosure, the reason why each edge is provided with the adjusting fasteners is to, firstly enable the staff to mount the tile display screens without considering arrangement positions of the first support plates 11 so as to improve convenience in mounting, and secondly enable to directly expand peripheral tile display screens when the number of the tile display screens is required to be increased; moreover, idle adjusting fasteners are used to adjust the transverse gap or the longitudinal gap between the newly expanded tile display screens and the tile display screens at edges.

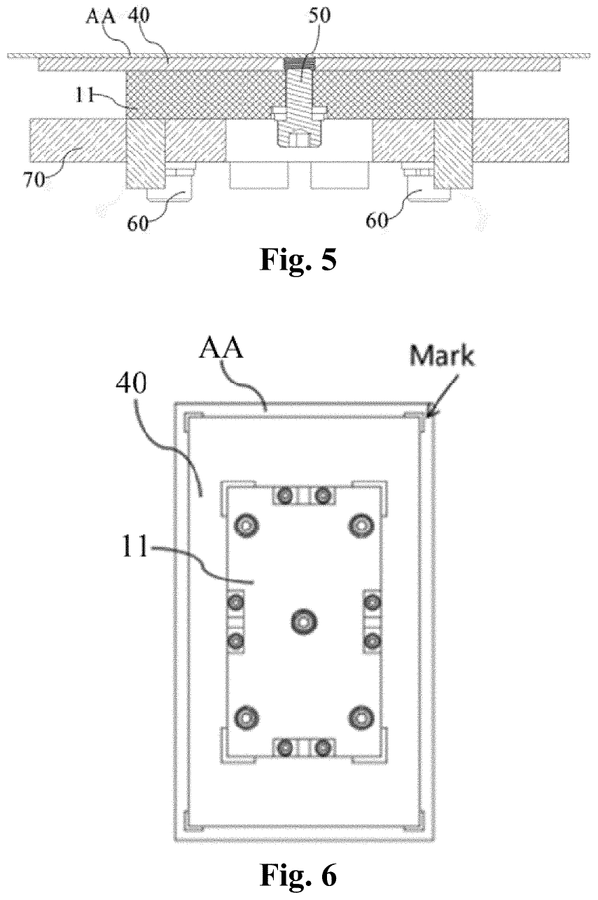

In an implementation of the disclosure, each edge of the first support plate 11 is only provided with only one adjusting fastener. Based on this, as shown in FIG. 4 and FIG. 5, the adjusting mechanism is further provided with third support plates 40 and first bolts 50. Each third support plate 40 is connected to one side, facing the tile display screen, of the first support plate 11 through each first bolt 50. When a tile display screen AA is tilted or reversed in mounting, the first bolt 50 may be screwed until the first support plate 11 is not clamped by the first bolt 50, in this state, the posture of the tile display screen AA may be adjusted by rotating the third support plate 40, thereby solving the problem of tilt or reverse in mounting of the tile display screen.

A first thread hole is defined in the middle of the third support plate 40, and a first through hole is defined in the middle of the first support plate 11. A diameter of the first through hole is greater than a nominal diameter of the first threaded hole. After the first bolt 50 penetrates the first through hole and then is screwed into the first threaded hole, a connection between the first support plate 11 and the third support plate 40 may be completed. The reason why the first through hole is configured as a through hole and the diameter of the first through hole is configured to be greater than the nominal diameter of the first threaded hole is to adjust the posture of the tile display screen without completely screwing the first bolt 50 out of the first threaded hole (if the first through hole is also configured as a threaded hole or the diameter thereof is configured to be smaller than that of the threaded hole, the third support plate 40 cannot rotate relative to the first support plate 11 before the first bolt 50 is completely screwed out of the first threaded hole, or the third support plate 40 is easy to be worn during rotating).

In an implementation, the third support plate 40 is provided with at least one alignment mark that is used to mark a fixation position of the tile display screen. The alignment mark can be set in many ways. For example, four L-shaped alignment marks are shown in FIG. 6. For another example, linear alignment marks are designed for marking the edges of the tile display screen up, down, left and right, which is not specifically limited in the disclosure.

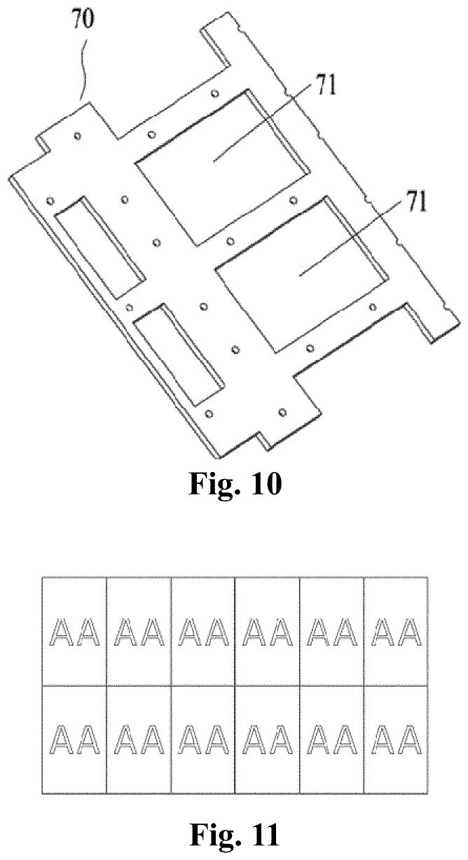

In another implementation of the disclosure, the second support plate 70 defines hollow portions 71 (as shown in FIG. 9 and FIG. 10). As shown in FIG. 7 and FIG. 8, each edge of the first support plate 11 is provided with two adjusting fasteners 80 that are exposed from the hollow portions 71. Two adjusting fasteners 80 on the same side are disposed in parallel and spaced apart from each other. When the tile display screen AA is tilted in mounting, for example, there is gap facing a lower end of the tile display screen AA while no gap facing an upper end thereof, the tilt of the tile display screen AA may be corrected by adjusting the interval between the adjusting fasteners 80 at the upper end, so that the problem of tilt in mounting of the tile display screen is solved.

The difference of the implementation over the foregoing implementation lies in: in this implementation, based on the principle of positioning a straight line at two points, the number of the adjusting fasteners is doubled, and the positions of the adjusting fasteners are adjusted, to achieve posture adjustment of the tile display screens, without configurations of the third support plates 40 and the first bolts 50. Thus, in this implementation, one surface, facing the tile display screen, of the first support plate 11 is provided with at least one alignment mark that is used to mark the fixation position of the tile display screen. The alignment mark is as described above, which is not repeated herein.

In this implementation, a tiling process of the tile display screens preferably implemented as follows. The tile display screens are first fixed to the first support plates 11 in one to one correspondence via glue or a double-side adhesive tape (preferably via a heat-conductive double-side adhesive tape, which plays a role in enhancing overall strength of a panel on the one hand, and may facilitate heat dissipation of an Micro Light-Emitting Diode (LED) display panel on the other hand, where the Micro LED display generally includes a glass layer, an Micro LED and a package adhesive layer, which is thin, and has low overall strength). The first support plates 11 is then connected to the second support plate 70 through a plurality of second bolts 60 (which are not locked deadly so as to facilitate subsequent accurate adjustment of positions of the tile display screens). Finally, it is determined whether a tiling gap is required to be adjusted or not according to the tiling effect. If it is required to adjust the tiling gap, the adjusting fixture 20 is mounted in the corresponding adjusting fasteners, at least one of the adjusting rods is rotated to reduce or eliminate the tiling gap. An arrangement relationship of the plurality of tile display screens after tiling is as shown in FIG. 11.

It is to be noted that in addition to the setting ways of the adjusting fasteners and the adjusting rods, many other ways are provided to adjust the positions of the tile display screens using the adjusting members in threaded connection, a few of which are listed as the following (there are many available structures in addition to the ways listed below, which cannot be listed one by one in the disclosure).

In an implementation, both the adjusting members are nuts. The nuts are connected to the first support plates 11 and move synchronously with the same. An adjusting screw is connected between the two nuts to form a split screw finally. A distance between the two nuts can be closed by rotating the adjusting screw.

In an implementation, both the adjusting members are screws. The screws are connected to the first support plates 11 and move synchronously with the same. A threaded sleeve is connected between the two screws. A distance between the two screws can be closed by rotating the threaded sleeve.

In an implementation, one of the two adjusting members is a screw and the other is a nut. The screw is rotatablely connected to one of the two adjacent first support plates 11, and the nut is fixedly connected to the other of the two adjacent first support plates 11. Because the nut is fixed, a distance between the two first support plates 11 can be closed by screwing the tail end of the screw into the nut.

In an implementation, both the adjusting members are nuts. The nuts are connected to the first support plates 11 and move synchronously with the same. In addition to the nuts, a screw that is penetratingly connected to the two nuts is also disposed. Threads of the two nuts are opposite in screwing. A distance between two first support plates 11 can be closed by rotating the screw clockwise or counterclockwise (different with difference in screwing directions of the two nuts).

According to another aspect of the disclosure, the second support plate defines a plurality of second through holes. The first support plates 11 define a plurality of second threaded holes corresponding to the second through holes one by one. A diameter of each second through hole is greater than a nominal diameter of each second threaded hole. The first support plates 11 and the second support plate 70 are connected through a plurality of second bolts 60 that respectively penetrate the second through holes and are screwed into the second threaded holes. It is to be noted that the reason why the diameter of the second through hole is greater than the nominal diameter of the second threaded hole is different from the reason why the diameter of the first through hole is greater than the nominal diameter of the first threaded hole. In order to ensure an enough moving space for the first support plates 11 relative to the second support plate 70, the diameter of the second through hole is configured to be greater than the nominal diameter of the second threaded hole.

In addition, the disclosure provides a tiled display device which includes at least two tile display screens and the adjusting mechanism for tile display screens described above. Thus, the tiled display device may have all features and effects of the above-mentioned adjusting mechanism for tile display screens, so no more elaboration will be made here.

It is to be understood that applications of the disclosure are not limited to the examples described above, those skilled in the art may make modifications or variations according to the foregoing description, and all these modifications and variations shall fall into the scope of protection of the disclosure.

What is claimed is:

1. An adjusting mechanism for tile display screens, wherein
the adjusting mechanism is configured to adjust a gap between two adjacent tile display screens and comprises first support plates and a second support plate, wherein each first support plate is configured to fix a corresponding one of the tile display screens, and the first support plates and the second support plate are movably connected; and
the adjusting mechanism further comprises adjusting fixtures, wherein each adjusting fixture is operable to be connected between the two adjacent first support plates and comprises two adjusting members in threaded connection, and a threaded connection length between the two adjusting members is adjustable so that the gap between the at least two tile display screens is adjusted.

2. The adjusting mechanism for tile display screens according to claim 1, wherein each edge of one surface, away from the tile display screen, of the first support plate is provided with at least one adjusting fastener which is exposed from a hollow portion disposed on the second support plate, and the adjusting fixture is clamped with the corresponding adjusting fasteners.

3. The adjusting mechanism for tile display screens according to claim 2, wherein each adjusting fastener defines a groove, and the two adjusting members of each adjusting fixture are respectively clamped in the grooves of the adjacent adjusting fasteners so as to connect the two adjacent support plates.

4. The adjusting mechanism for tile display screens according to claim 3, wherein each adjusting member comprises a retaining portion clamped with the corresponding groove, and limiting portions respectively disposed at two ends of the retaining portion.

5. The adjusting mechanism for tile display screens according to claim 4, wherein the groove is in a U-shape.

6. The adjusting mechanism for tile display screens according to claim 2, wherein the adjusting fasteners comprise longitudinal adjusting fasteners and transverse adjusting fasteners, the longitudinal adjusting fasteners are configured to cooperate with the adjusting fixtures to adjust a longitudinal gap between the tile display screens, and the transverse adjusting fasteners are configured to cooperate with the adjusting fixtures to adjust a transverse gap between the tile display screens.

7. The adjusting mechanism for tile display screens according to claim 1, wherein one surface, facing the tile display screen, of the first support plate is provided with at least one alignment mark that is used to mark a fixation position of the tile display screen.

8. The adjusting mechanism for tile display screens according to claim 1, wherein one surface, facing the tile display screen, of the first support plate is provided with a third support plate, each third support plate is configured to fix a corresponding one of the tile display screens, and the first support plate is movably connected with the third support plate.

9. The adjusting mechanism for tile display screens according to claim 8, wherein each third support plate is provided with at least one alignment mark that is used to mark a fixation position of the corresponding one of the tile display screens.

10. The adjusting mechanism for tile display screens according to claim 8, wherein a first threaded hole is formed in the middle of each third support plate, a first through hole is formed in the middle of each first support plate, and the first support plate and the third support plate are connected through a first bolt that penetrates the first through hole and is screwed into the first threaded hole.

11. The adjusting mechanism for tile display screens according to claim 10, wherein a diameter of the first through hole is greater than a nominal diameter of the first threaded hole.

12. The adjusting mechanism for tile display screens according to claim 1, wherein each edge of the first support plate is provided with two adjusting fasteners that are exposed from hollow portions disposed on the second support plate, and two adjusting fasteners on the same side are disposed in parallel.

13. The adjusting mechanism for tile display screens according to claim 1, wherein the second support plate defines a plurality of second through holes, the first support plates define a plurality of second threaded holes corresponding to the second through holes one by one, and the first support plates and the second support plate are connected through second bolts that respectively penetrate the second through holes and are screwed into the second threaded holes.

14. The adjusting mechanism for tile display screens according to claim 13, wherein a diameter of the second through hole is greater than a nominal diameter of the second threaded hole.

15. A tiled display device, comprising at least two tile display screens and an adjusting mechanism for tile display screens, wherein a gap between the at least two tile display screens is adjusted through the adjusting mechanism for tile display screens, wherein
the adjusting mechanism comprises first support plates and a second support plate, wherein each first support plate is configured to fix a corresponding one of the tile display screens, and the first support plates and the second support plate are movably connected; and
the adjusting mechanism further comprises adjusting fixtures, wherein each adjusting fixture is operable to be connected between the two adjacent first support plates and comprises two adjusting members in threaded connection, and a threaded connection length between the two adjusting members is adjustable so that the gap between the at least two tile display screens is adjusted.

16. The tiled display device according to claim 15, wherein each edge of one surface, away from the tile display screen, of the first support plate is provided with at least one adjusting fastener which is exposed from a hollow portion disposed on the second support plate, and the adjusting fixture is clamped with the corresponding adjusting fasteners.

17. The adjusting mechanism for tile display screens according to claim 16, wherein each adjusting fastener defines a groove, and the two adjusting members of each adjusting fixture are respectively clamped in the grooves of the adjacent adjusting fasteners so as to connect the two adjacent support plates.

18. The adjusting mechanism for tile display screens according to claim 17, wherein each adjusting member comprises a retaining portion clamped with the corresponding groove, and limiting portions respectively disposed at two ends of the retaining portion.

19. The adjusting mechanism for tile display screens according to claim 18, wherein the groove is in a U-shape.

20. The adjusting mechanism for tile display screens according to claim 16, wherein the adjusting fasteners comprise longitudinal adjusting fasteners and transverse adjusting fasteners, the longitudinal adjusting fasteners are configured to cooperate with the adjusting fixtures to adjust a longitudinal gap between the tile display screens, and the transverse adjusting fasteners are configured to cooperate with the adjusting fixtures to adjust a transverse gap between the tile display screens.
